(19) United States
(12) Patent Application Publication
(10) Pub. No.: US 2026/0255880 A1
(43) Pub. Date: Aug. 27, 2026

(54) METHOD FOR PRODUCING A MEMS CONVERTER USING A STRETCHING OF AN ACTUATOR MATERIAL

(71) Applicant: Hahn-Schickard-Gesellschaft für angewandte Forschung e. V., Villingen-Schwenningen (DE)

(72) Inventors: Achim Bittner, Heilbronn (DE); Steffen Keller, Konstanz (DE); Dennis Becker, Donaueschingen (DE); Alfons Dehé, Reutlingen (DE)

(21) Appl. No.: 18/877,955

(22) PCT Filed: Jun. 20, 2023
(86) PCT No.: PCT/EP2023/066534

§ 371 Date: Dec. 20, 2024

(30) Foreign Application Priority Data
Jun. 21, 2022 (EP) 22180086.5

(51) Int. Cl. H10N 30/085; H04R 17/00; H04R 31/00; H10N 30/098; H10N 30/857

(52) U.S. Cl. CPC H10N 30/085; H04R 31/00; H10N 30/098; H04R 17/005; H10N 30/857

(57) ABSTRACT

The invention relates to a method for producing a MEMS transducer for interacting with a volume flow of a fluid. For this purpose, a shaping component for forming a vibratable membrane with an actuator layer in the form of a meander structure and an actuator material comprising polymers are first provided, wherein the actuator material is present in the form of a polymer foil or a polymer liquid. In order to obtain the shape of the actuator layer of the vibratable membrane, the shaping component is placed in contact with the actuator material. Advantageously, during the contact between the shaping component and the actuator material, the polymers of the actuator material are aligned and/or stretched such that a dipole moment of the polymers is increased and piezoelectric properties of the actuator material are enhanced. In a further aspect, the invention relates to a MEMS transducer which can be produced using the method.

The invention relates to a method for producing a MEMS transducer for interacting with a volume flow of a fluid. For this purpose, a shaping component for forming a vibratable membrane with an actuator layer in the form of a meander structure and an actuator material comprising polymers are first provided, wherein the actuator material is present in the form of a polymer foil or a polymer liquid. In order to obtain the shape of the actuator layer of the vibratable membrane, the shaping component is placed in contact with the actuator material. Advantageously, while the shaping component and the actuator material are in contact, the polymers of the actuator material are aligned and/or stretched such that a dipole moment of the polymers and piezoelectric properties of the actuator material are enhanced.

In a further aspect, the invention relates to a MEMS transducer which can be produced using the method.

### BACKGROUND AND PRIOR ART

Today, microsystems technology is used in many areas of application for the production of compact, mechanical-electronic devices. The microelectromechanical systems (MEMS for short) that can be produced in this way are very compact (micrometer range) with outstanding functionality and ever lower production costs.

MEMS transducers, such as MEMS loudspeakers or MEMS microphones, are also known from the prior art. Current MEMS loudspeakers are usually designed as planar membrane systems with vertical actuation of a vibratable membrane in the direction of emission. The membranes are induced to vibrate, for example, by means of piezoelectric, electromagnetic or electrostatic actuators.

An electromagnetic MEMS loudspeaker for mobile devices is described in Shahosseini et al. 2015. The MEMS loudspeaker exhibits a reinforcing silicon microstructure as a sound radiator, wherein the moving part is suspended from a carrier via silicon drivers to enable large out-of-plane displacements by means of an electromagnetic motor.

Stoppel et al. 2017 discloses a two-way loudspeaker whose concept is based on concentric piezoelectric actuators. As a special feature, the vibrating membrane is not closed, but comprises eight piezoelectric unimorph actuators, each consisting of a piezoelectric and a passive layer. The outer woofers consist of four trapezoidal actuators clamped on one side, while the inner tweeters are formed by four triangular actuators connected to a rigid frame by one or more springs. The separation of the membrane is intended to allow an improved sound pattern with higher output.

One disadvantage of such planar MEMS loudspeakers is their limitation in terms of sound power, in particular at low frequencies. One reason for this is that the sound pressure level that can be generated is proportional to the square of the frequency for a given displacement. Sufficient sound power therefore requires either displacements of at least 100 μm for vibrating membranes or in the square centimeter range for large-area membranes. Both conditions are difficult to achieve using MEMS technology.

In the prior art, it was therefore proposed to design MEMS loudspeakers that do not exhibit a closed membrane for vibrations in the vertical emission direction, but rather a plurality of movable elements that can be induced into lateral or horizontal vibrations. The advantage of this is that an increased volume flow can be moved on a small surface area and thus an increased sound power can be provided.

A MEMS loudspeaker based on this principle is disclosed, for example, in US 2018/0179048 A1 and Kaiser et al. 2019. The MEMS loudspeaker comprises a plurality of electrostatic bending actuators, which are arranged as vertical lamellae between a top and bottom wafer and can be induced into lateral vibrations by appropriate control. An inner lamella forms an actuator electrode opposite two outer lamellae. Apart from a connecting node of electrodes that are still galvanically separated, there is an air gap between the three curved lamellae. If a potential is applied inside against outside, this leads to an attraction on both sides due to the curvature of the design in the direction of a preferred direction, which is specified by an armature. The curvatures of the outer lamellae facilitate movability. The restoring force is provided by a mechanical spring force. Pull-push operation is therefore not possible.

Another disadvantage is that gaps between the bending actuators and the top/bottom wafers, which are necessary for their movability, lead to ventilation between the two chambers. This limits the lower cut-off frequency. Furthermore, the lateral movement of the bending actuators and therefore the sound power is restricted in order to avoid a pull-in effect and acoustic breakdown.

DE 10 2017 115 923 A11 discloses a method for producing a MEMS transducer that can be used in microphones or loudspeakers. For the production of the MEMS transducer, a negative form is provided by a substrate and optionally a sacrificial layer, by means of which the structure of the membrane can be predetermined. The substrate or the negative form exhibits recesses that correspond to wave peaks or wave troughs of the membrane. The negative form is then coated with an electrically conductive layer and a piezoelectric layer. To expose the membrane, the negative form or the substrate is partially removed such that a holder for the membrane is also provided by the partial removal of the substrate.

US 2018/0035229 A1 also relates to a MEMS transducer, in particular a capacitive MEMS microphone or MEMS loudspeaker. Here, a pair of electrodes is attached to the membrane itself in order to reduce measurement noise in MEMS transducers with a rigid backplate. The pair of electrodes comprises a first conductive element and a second conductive element, which experience distance variations due to the displacement of the membrane, whereby a capacitance can be measured. In order to achieve a distance variation between the electrodes, the membrane can exhibit corrugations. To produce the MEMS transducer with a membrane comprising a corrugation, a coating of a plurality of layers is applied to a substrate which is provided with a recess. To expose the membrane, the rear side of the substrate is etched.

WO 2021/144400 A1 discloses a MEMS transducer that can be used both as a MEMS loudspeaker and as a MEMS microphone. The MEMS transducer described therein exhibits a vibratable membrane which is constructed in such a way that it comprises two or more vertical sections which are substantially parallel to the vertical direction. Furthermore, the vibratable membrane comprises at least one layer of an actuator material and is in contact with at least one electrode at its end. This allows the vertical sections to be induced into horizontal vibrations by driving the electrode. Conversely, an electrical signal can also be generated at the electrode when the vertical sections are induced to vibrate horizontally.

The MEMS transducer disclosed in WO 2021/144400 A1 exhibits significant improvements over the prior art. In the case of a MEMS loudspeaker, the configuration of the vibratable membrane comprising the vertical sections advantageously entails a higher sound power, wherein the contact simultaneously ensures simplified controllability. In the case of a MEMS microphone, a higher performance and audio quality with a suitable sound pattern is also advantageously made possible. In addition, proven semiconductor processing methods can be used to produce the MEMS transducer, enabling cost-efficient production.

The MEMS transducer disclosed in WO 2021/144400 A1 is preferably produced by etching a substrate, preferably from a front side, to form a meander structure. At least two layers are then applied, wherein at least a first layer comprises an actuator material and a second layer comprises a mechanical support material, or at least two layers comprising an actuator material are coated. The first and/or the second layer are then placed in contact with an electrode.

There is potential for optimization, particularly with regard to the production process of the MEMS transducer disclosed in WO 2021/144400 A1. In particular, the application of the actuator material to the meander structure formed in the substrate is complex in order to ensure a homogeneous coating. However, a uniform configuration of the vibratable membrane is of great importance for the acoustic performance.

All MEMS transducers known in the prior art, such as MEMS loudspeakers or MEMS microphones, have in common that the vibratable membrane is of particular importance. Only the displacement of the membrane allows the detection or generation of a signal. The material selection as such is of particular importance, in particular the material selection of the actuator material which is used in the production process of the MEMS transducer disclosed in WO 2021/144400 A1 for application to the meander structure of the substrate. On the one hand, the desired acoustic, mechanical and electrical properties must be fulfilled in order to enable the MEMS transducer to function properly. On the other hand, the material must also be easy to process in order to optimize the production of the membrane and thus also of the MEMS transducer.

In light of the prior art, there is therefore a need to provide improved or alternative methods for producing a MEMS transducer.

### OBJECTIVE OF THE INVENTION

The objective of the invention was to eliminate the disadvantages of the prior art. In particular, one objective of the invention was to provide a method for producing MEMS transducers which is characterized by a high process efficiency and reliably results in a high-performance MEMS transducer with desired acoustic properties.

### SUMMARY OF THE INVENTION

The objective of the invention is solved by the independent claims. Advantageous embodiments of the invention are disclosed in the dependent claims.

In a first aspect, the invention relates to a method for producing a MEMS transducer for interacting with a volumetric flow of a fluid comprising
a carrier
a vibratable membrane for generating or receiving pressure waves of the fluid in a vertical
direction, wherein the vibratable membrane is supported by the carrier, the vibratable membrane exhibits a meander structure with vertical sections and horizontal sections, wherein the vertical sections are formed substantially parallel to the vertical direction and the horizontal sections connect the vertical sections to one another, and wherein the vibratable membrane comprises at least one actuator layer made of an actuator material and is in contact with at least one electrode, such that the vertical sections can be induced into horizontal vibrations by driving the at least one electrode or such that an electrical signal can be generated at the at least one electrode when the vertical sections are induced to vibrate horizontally, wherein the method comprises the following steps:
a) provision of at least one shaping component for forming the vibratable membrane with the actuator layer in the form of a meander structure,
b) providing an actuator material comprising polymers, wherein the actuator material is present in the form of a polymer foil or a polymer liquid,
c) placing the shaping component in contact with the actuator material for shaping the actuator layer, wherein during the contact between the shaping component and the actuator material, the polymers of the actuator material are aligned and/or stretched such that a dipole moment of the polymers is increased and piezoelectric properties of the actuator material are enhanced.

The preferred method for producing a MEMS transducer has proven to be advantageous in a plurality of aspects.

One particular advantage is that the piezoelectric properties of the actuator material can be enhanced, in particular through the use of an actuator material comprising polymers and the alignment and/or stretching of the polymers. An enhancement of the piezoelectric properties preferably means that physical parameters with regard to the piezoelectric effect can be advantageously increased. Relevant physical parameters preferably relate to piezoelectric charge coefficients, piezoelectric voltage coefficients and/or piezoelectric coupling coefficients.

The preferred contact of the shaping component with the actuator material for shaping the actuator layer serves in particular to provide the vibratable membrane of the MEMS transducer. By enhancing the piezoelectric properties, it is advantageously possible to provide a vibratable membrane that generates a correspondingly higher electrical measurement signal when the vertical sections are displaced. Conversely, by applying an electrical voltage, a greater displacement of the vertical sections can be generated such that a higher volume flow can be emitted. As a result, the preferred method is ideally suited for providing a high-performance MEMS microphone or a MEMS loudspeaker as a MEMS transducer with desired acoustic properties.

According to the invention, it was recognized that an actuator material comprising polymers with the characteristic of attaining enhanced piezoelectric properties in the event of alignment and/or stretching of the polymers is ideally suited for use in a method for producing a MEMS transducer. Here, a particularly powerful actuator layer can be ensured with low material costs and efficient process control, which leads to high sensitivity in the case of a MEMS microphone or high power in the case of a MEMS loudspeaker.

The advantageous effect of increasing the piezoelectric properties is preferably based on an increase in the dipole moment of the polymers of the actuator material. In the context of the invention, the dipole moment preferably refers to an electric dipole moment, which is a measure of the spatial charge separation and thus preferably a measure of the strength of the dipole character of the polymers of the actuator material.

Without wishing to be limited to theory, it is preferred in the context of the invention that the piezoelectric properties of the actuator layer formed are enhanced by the alignment and/or stretching of the polymers of the actuator material. The molecular and/or submolecular structure of the polymers is relevant for the adjustment of the optimized piezoelectric properties.

Stretching preferably means that the contact between the shaping component and the actuator material causes the atoms and/or molecules of a polymer to be spaced further apart, which preferably increases the spatial separation of the partial charges of the atoms and/or molecules. Accordingly, polarization occurs and the piezoelectric properties are enhanced.

Alignment preferably means that the molecules and/or atoms of the polymers of the actuator material are arranged in such a way that an oriented charge distribution occurs in order to enhance the piezoelectric properties. Thus, an alignment preferably comprises an arrangement of the atoms and/or molecules with different electronegativities in order to increase the dipole moment. In particular, atoms and/or molecules with a high electronegativity and a low electronegativity are aligned in such a way that the polarization and thus the piezoelectric properties are increased. It may be preferred for certain material phases to be obtained by aligning the atoms and/or molecules. For example, in the case of polyvinyl difluoride (PVDF), a β-phase can be achieved by aligning the polymers, which has proven to be particularly advantageous in the context of the invention.

The preferred method steps are particularly suitable for providing a high-performance actuator layer (i.e. the actuator material after contact with the shaping component) as part of a vibratable membrane, which exhibits excellent performance due to the enhanced piezoelectric properties. There are also a number of resulting advantages in terms of processing.

Thus, MEMS transducers can be advantageously produced in a hybrid manner by using an actuator material comprising polymers. Therefore, the scaling of production can be advantageously cost-effective. In particular, costs for equipment and manufacturing infrastructure can be lower compared to CMOS (complementary metal-oxide-semiconductor) manufacturing, depending on the application. The use of an actuator material comprising polymers facilitates production, as polymers are inexpensive to purchase, easy to process and exhibit a high degree of mechanical flexibility. Both in liquid form and as a polymer foil, the actuator layer can advantageously be applied particularly homogeneously to the shaping component, wherein enhanced piezoelectric properties of the actuator material are ensured at the same time by stretching and/or alignment.

At the same time, a further material, e.g. a mechanical support material and/or an electrically conductive material, can also be applied to the actuator layer in a simple manner. Accordingly, it is possible to provide mechanical stability, a protective function and/or contact for the actuator layer on a front and rear side of the actuator layer. The other layer (e.g. a mechanical support material and/or an electrically conductive material) can be applied both before and after contact with the shaping component, such that there is a high degree of flexibility in terms of process control.

The preferred method also advantageously allows the vibratable membrane to be formed in a particularly precise manner. Thus, by placing the shaping component in contact with the actuator material, particularly fine dimensions of the vertical and/or horizontal sections of the vibratable membrane can be advantageously achieved, wherein a uniform configuration of the actuator layer is ensured at the same time.

The preferred method is also quick and easy to carry out, requires comparatively inexpensive materials, components and/or equipment and is characterized by high process efficiency.

A shaping component is preferably provided first. The shaping component is preferably used to make contact with the actuator material in order to form the actuator layer.

The actuator material comprising polymers is preferably in the form of a polymer foil or a polymer liquid. Preferably, the shaping component is placed in contact with the actuator material for shaping the actuator layer. Shaping preferably means establishing the form or structure of the vibratable membrane. In particular, shaping relates to obtaining the actuator layer after the shaping component is placed in contact with the actuator material. Preferably, shaping relates to the formation of a meander structure which exhibits vertical sections and horizontal sections.

During contact between the shaping component and the actuator material, the polymers of the actuator material are aligned and/or stretched such that a dipole moment of the polymers is increased and piezoelectric properties of the actuator material are enhanced. The prior art describes materials that gain polarization and thus achieve pronounced piezoelectric properties. These are described, for example, in Da Silva et al. (2010) and Gade, Bokka & Chase (2021). In Da Silva et al. (2010) it is shown that the β-phase of PVDF can be obtained by crystallization of N,N-dimethylformamide solution. Gade, Bokka & Chase (2021) discusses the production of PVDF fiber mats and fiber yarns and the measurement of their charge with a special Faraday cage construction. The person skilled in the art does not receive any indications of applicability for the production of a MEMS transducer. However, the inventors have recognized that materials comprising polymers which achieve an increased polarization when the polymers are stretched and/or aligned are particularly suitable for providing an actuator layer for a MEMS transducer. In addition to the high degree of process efficiency, the increased performance of the actuator layer due to the adjustable polarization combined with excellent sound characteristics is particularly beneficial.

Advantageously, the preferred method can therefore provide a MEMS transducer that is particularly suitable in terms of its acoustic properties.

The design of the MEMS transducer advantageously combines the possibility of high sound power with simplified control. In contrast to known planar MEMS loudspeakers, for example, the vibratable membrane itself does not have to be operated over a large area of a plurality of square centimeters or with displacements of more than 100 μm in order to generate sufficient sound pressure. Instead, the majority of the vertical sections of the vibratable membrane can move an enlarged total volume in the vertical emission direction with small horizontal or lateral movements of a few micrometers.

At the same time, simplified control can be achieved. Whereas in the prior art, such as in US 2019/011 64 17 A1, a plurality of piezoelectric actuators have to be in contact with the horizontal sections, the MEMS loudspeaker described here can be operated by means of at least one electrode, preferably at the end. This reduces the production complexity, minimizes sources of error and also inherently leads to synchronous control of the vertical sections to vibrate horizontally.

In this way, the air volumes present between the vertical sections can be moved extremely precisely along the vertical emission direction by the horizontal vibrations.

This also makes it possible to provide a particularly powerful MEMS microphone with high audio quality. The structure of the MEMS microphone is structurally similar to that of the MEMS loudspeaker, particularly with regard to the configuration of the vibratable membrane. However, instead of driving the electrodes to generate horizontal vibrations and thus sound pressure waves, the MEMS microphone is configured to receive sound pressure waves in the same vertical direction. Preferably, volumes of air are present between the vertical sections, which are moved along a vertical detection direction when sound waves are received. The sound pressure waves induce the vertical sections to vibrate horizontally, such that the actuator material generates a corresponding periodic electrical signal.

The obtained actuator layers with enhanced polarization properties have proven to be extremely advantageous for the performance and vibration behavior of the membrane, both with regard to applications as a MEMS loudspeaker and as a MEMS microphone.

The producible MEMS transducer is also less complex and allows further processing steps to be carried out easily, for example the appropriate placement of a top and/or bottom electrode on the vibratable membrane.

The preferred method is used in particular to produce a MEMS transducer. The term MEMS transducer refers to both a MEMS microphone and a MEMS loudspeaker. In general, the MEMS transducer refers to a transducer for interacting with a volume flow of a fluid, which is based on MEMS technology and whose structures for interacting with the volume flow or for receiving or generating pressure waves of the fluid exhibit dimensions in the micrometer range (1 μm to 1,000 μm). The fluid can be either a gaseous or a liquid fluid. The structures of the MEMS transducer, in particular the vibratable membrane, are configured to generate or receive pressure waves of the fluid.

For example, as in the case of a MEMS loudspeaker or MEMS microphone, these can be sound pressure waves. However, the MEMS transducer can also be suitable as an actuator or sensor for other pressure waves. The MEMS transducer is therefore preferably a device or apparatus that converts pressure waves (e.g. acoustic signals as sound pressure waves) into electrical signals or vice versa (conversion of electrical signals into pressure waves, for example acoustic signals).

Applications of the MEMS transducer as an energy harvester are also possible, wherein pneumatic or hydraulic alternating pressures are used. In these cases, the electrical signal can be discharged as recovered electrical energy, stored or fed to other (consumer) devices.

A MEMS loudspeaker preferably refers to a loudspeaker that is based on MEMS technology and whose sound-generating structures at least partially exhibit dimensions in the micrometer range (1 μm to 1000 μm). Preferably, for example, the vertical sections of the vibratable membrane can exhibit a dimension in the range of less than 1000 μm in width, height and/or thickness. It may also be preferred, for example, that only the height of the vertical sections is dimensioned in the micrometer range, while, for example, the length may exhibit a larger dimension and/or the thickness a smaller magnitude.

A MEMS microphone preferably refers to a microphone that is based on MEMS technology and whose sound-receiving structures at least partially exhibit dimensions in the micrometer range (1 μm to 1000 μm). Preferably, for example, the vertical sections of the vibratable membrane can exhibit a dimension in the range of less than 1000 μm in width, height and/or thickness. It may also be preferred, for example, that only the height of the vertical sections is dimensioned in the micrometer range, while, for example, the length may exhibit a larger dimension and/or the thickness a smaller magnitude.

Preferably, the MEMS transducer comprises the vibratable membrane for generating or receiving pressure waves of the fluid in a vertical direction. The vibratable membrane thus refers to the structure that makes it possible to generate an electrical signal after pressure waves have been received or to generate pressure waves by applying an electrical signal. For this purpose, it is preferred that the vibratable membrane exhibits at least one actuator layer made of an actuator material. Preferably, the vibratable membrane is structured in such a way that it exhibits a meander structure comprising vertical and horizontal sections.

A meander structure preferably refers to a structure formed from a sequence of sections that are substantially orthogonal in cross-section. The mutually orthogonal sections are preferably vertical and horizontal sections of the vibratable membrane. It is particularly preferred that the meander structure is rectangular in cross-section. However, it may also be preferred for the meander structure to exhibit a sawtooth shape (zig-zag shape) in cross-section or to be curved or undulating. This is the case in particular if the vertical sections are not aligned exactly parallel to the vertical emission or detection direction, but form an angle of ±30°, preferably ±20°, particularly preferably ±10° with the vertical direction.

In preferred embodiments, the horizontal sections may also not be at an exact orthogonal angle of 90° to the vertical emission or detection direction, but may, for example, include an angle between 60° and 120°, preferably between 70° and 110°, particularly preferably between 80° and 100° with the vertical direction.

Preferably, the vertical and/or horizontal sections are rectilinear at least in sections or over their entire length, however the vertical and/or horizontal sections can also be curved at least in sections or over their entire length. In the case of a curved or undulating shape of the vertical and/or horizontal sections of the vibratable membrane in cross-section, alignment preferably refers to a tangent to the vertical and/or horizontal sections at their respective centers.

While the vibratable membrane is preferably aligned horizontally to the sound emission direction or sound detection direction, the sound waves are generated or detected by actuation of the vertical sections.

Preferably, the layer of an actuator material in the vertical sections serves as a component of a mechanical biomorph, wherein a lateral curvature of the vertical sections is caused by driving the actuator layer via the electrode or wherein a corresponding electrical signal is generated by an induced lateral curvature. A bimorph preferably refers to a structure that comprises two layers, wherein a displacement and/or curvature is made possible by the interaction of the two layers.

In a preferred embodiment, the vertical sections exhibit at least two layers, wherein one layer comprises an actuator material and a second layer comprises a mechanical support material and wherein at least the layer comprising the actuator material is in contact with an end-side electrode, such that the horizontal vibrations can be generated by a change in shape of the actuator material relative to the mechanical support material. Thus, in said preferred embodiment, a vertical section is present as a mechanical bimorph. In the embodiment, the mechanical bimorph is formed by a layer of actuator material (e.g. a piezoelectric material) and a passive layer, which acts as a mechanical support layer. In the mechanical bimorph, the actuator material is preferably already present as an actuator layer.

Advantageously, by providing the actuator layer by aligning and/or stretching the polymers of the actuator material, the piezoelectric properties can be adjusted particularly well. A higher degree of stretching and/or alignment of the actuator material can, for example, generate a greater distance of the partial charges of atoms and/or molecules of the polymers of the actuator material. This increases the dipole moment such that the piezoelectric properties are enhanced. Conversely, the distance of the partial charges of atoms and/or molecules of the polymers of the actuator material can be reduced by reducing the stretching and/or alignment of the actuator material. As a result, the dipole moment is increased to a lesser extent, such that the piezoelectric properties are less pronounced. By stretching and/or aligning the actuator material accordingly, the sensitivity of the actuator layer can be precisely adjusted in the context of use as a bimorph. The alignment and/or stretching of the polymers of the actuator material and thus the piezoelectric properties can be adjusted, for example, by selecting stretching factors, which will be described in more detail below.

Both a transverse and longitudinal piezoelectric effect can be used to bend the bimorph. With the direct longitudinal piezoelectric effect, the application of force and thus the resulting stress gradient is caused by the pressure waves along polar axes. In the inverse longitudinal piezo effect, the stress is applied along a non-polar axis, which leads to the expansion of the elementary cell along a polar axis of the actuator layer. A polar axis preferably means an axis that runs between two centers of charge, preferably between two unequal centers of charge. In the case of the direct transverse piezo effect, the force is applied along a non-polar axis by pressure waves, such that an electrical signal can be measured at the electrode. The non-polar axis is preferably an axis that does not run along two centers of charge. In the inverse transverse piezo effect, the stress is applied along a polar axis, which leads to the expansion of the elementary cell along a non-polar axis of the actuator layer. A transverse piezo effect can be used to advantage with a C-axis orientation of the actuator layer.

When the actuator layer is driven, it can undergo transverse or longitudinal stretching or compression, for example. This creates a stress gradient in relation to the mechanical support layer, which leads to a lateral curvature or vibration. By alternating the polarity of the electrodes, preferably a push-pull operation can be achieved, whereby almost the entire air volume can be moved in an alternating manner between the vertical sections in the vertical emission direction. The stretching and/or alignment of the polymers of the actuator material and the associated increase in the dipole moment and enhancement of the piezoelectric properties of the actuator layer result in particularly high performance. In particular, the performance in push-pull operation can be precisely adjusted during production depending on the application. The advantage of the actuator principle is thus a highly efficient translation of the horizontal vibrations of vertical sections into a vertical volume movement or sound generation.

As the actuator principle is not based on electrostatic attraction, but on a relative change in shape (e.g. compression, stretching, shearing) of the actuator layer in relation to a support layer, the possibility of the membrane sections sticking together can be ruled out. Instead, the vertical sections can touch each other at their ends and are therefore not restricted in their displacement.

In a further preferred embodiment, the vertical sections comprise at least two layers, wherein both layers comprise an actuator material and are preferably in contact with electrodes at their ends and the horizontal vibrations can be generated by a change in shape of one layer relative to the other layer. In the embodiment, the horizontal vibration of the vertical sections is therefore not generated by a stress gradient between an active actuator layer and a passive support layer, but by a relative change in shape of two active actuator layers. A vertical section is therefore also present as a bimorph in this embodiment.

The actuator layers can consist of the same actuator material and be driven differently. The actuator layers can also consist of different actuator materials, for example piezoelectric materials with different deformation coefficients. The actuator layers are preferably formed as described by stretching and/or aligning the polymers of an actuator material, wherein the extent of the stretching and/or alignment can advantageously also be used to adjust the deformation coefficients. Deformation coefficients preferably refer to material variables that can be used to quantify a displacement and/or vibration capacity. For example, two different actuator materials can be provided, which together undergo an alignment and/or stretching of their different polymers. Consequently, by aligning and/or stretching the polymers of the two actuator materials, different deformation coefficients can be used to regulate the displacement capacity of the vertical sections.

In the context of the invention, the “layer comprising an actuator material” is preferably also referred to as the actuator layer.

In the context of the invention, the “layer comprising a mechanical support material” is preferably also referred to as a support layer. The mechanical support material or the support layer preferably serves as a passive layer which can resist a change in shape of the actuator layer. In contrast to an actuator layer, the mechanical support material preferably does not change its shape when an electrical voltage is applied. Preferably, the mechanical support material is electrically conductive, such that it can also be used directly for establishing contact with the actuator layer. In some embodiments, however, it can also be non-conductive and coated with an electrically conductive layer, for example.

The mechanical support material is preferably monocrystalline silicon, polysilicon or doped polysilicon.

While the actuator layer undergoes a change in shape when subject to an electrical voltage, the position of the mechanical support material remains substantially unchanged. The resulting stress gradient between the two layers (mechanical bimorph) preferably causes a horizontal curvature. For this purpose, the thickness of the support layer should preferably be selected in relation to the thickness of the actuator layer so that a sufficiently large stress gradient is generated for the curvature.

The meander structure preferably corresponds to a membrane folded along its width. In the context of the invention, a vibratable membrane can therefore preferably also be referred to as a bellows. The parallel folds of the bellows preferably form the vertical sections. The connecting sections between the folds preferably form the horizontal sections. Preferably, the vertical sections are longer than the horizontal sections, for example by a factor of 1.5, 2, 3, 4 or more. The horizontal sections preferably denote those structures that enable a connection between two or more vertical sections.

The performance of the MEMS transducer, in particular a MEMS loudspeaker or MEMS microphone, can be significantly determined by the number and/or dimensions of the vertical sections.

In preferred embodiments, the vibratable membrane comprises more than 3, 4, 5, 10, 15, 20, 30, 40, 50, 100 or more vertical sections.

In further preferred embodiments, the vibratable membrane comprises less than 10000, 5000, 2000 or 1000 or fewer vertical sections.

The preferred number of vertical sections entails high sound power levels on the smallest chip surfaces without compromising the sound pattern or audio quality.

Preferably, the vertical sections are planar, which means in particular that their extension in each of the two dimensions (height, width) of their surface is greater than in a dimension perpendicular to this (thickness). For example, size ratios of at least 2:1, preferably at least 5:1, 10:1 or more may be preferred.

In the context of the invention, the height of the vertical sections preferably corresponds to the dimension along the direction of sound emission or sound detection, while the thickness of the vertical sections preferably corresponds to the sum of the layer thickness of the one or more layers forming the vertical sections. The length of the vertical sections preferably corresponds to a dimension orthogonal to the height or thickness. In the cross-sectional views of the figures shown below, the height and thickness are shown schematically (not necessarily true to scale), while the dimension of the length corresponds to a (non-visible) drawing depth of the figures.

In a preferred embodiment, the height of the vertical sections is between 1 μm and 1000 μm, preferably between 10 μm and 500 μm. Intermediate ranges from the aforementioned ranges may also be preferred, such as 1 μm to 10 μm, 10 μm to 50 μm, 50 μm to 100 μm, 100 μm to 200 μm, 200 μm to 300 μm, 300 μm to 400 μm, 400 μm to 500 μm, 600 μm to 700 μm, 700 μm to 800 μm, 800 μm to 900 μm or even 900 μm to 1000 μm. A person skilled in the art will recognize that the aforementioned range limits can also be combined to obtain further preferred ranges, such as 10 μm to 200 μm, 50 μm to 300 μm or even 100 μm to 600 μm.

In a preferred embodiment, the thickness of the vertical sections is between 100 nm and 10 μm, preferably between 500 nm and 5 μm. Intermediate ranges from the aforementioned ranges can also be preferred, such as 100 nm to 500 nm, 500 nm to 1 μm, 1 μm to 1.5 μm, 1.5 μm to 2 μm, 2 μm to 3 μm, 3 μm to 4 μm, 4 μm to 5 μm, 5 μm to 6 μm, 6 μm to 7 μm, 7 μm to 8 μm, 8 μm to 9 μm or even 9 μm to 10 μm. A person skilled in the art will recognize that the aforementioned range limits can also be combined to obtain further preferred ranges, such as 500 nm to 3 μm, 1 μm to 5 μm or even 1500 nm to 6 μm.

In a preferred embodiment, the length of the vertical sections is between 10 μm and 10 mm, preferably between 100 μm and 1 mm. Intermediate ranges from the aforementioned ranges can also be preferred, such as 10 μm to 100 μm, 100 μm to 200 μm, 200 μm to 300 μm, 300 μm to 400 μm, 400 μm to 500 μm, 500 μm to 1000 μm, 1 mm to 2 mm, 3 mm to 4 mm, 4 mm to 5 mm, 5 mm to 8 mm or even 8 mm to 10 mm. A person skilled in the art will recognize that the aforementioned range limits can also be combined to obtain further preferred ranges, such as 10 μm to 500 μm, 500 μm to 5 μm or even 1 mm to 5 mm.

With the aforementioned preferred dimensions of the vibratable membrane or the vertical sections, a particularly compact MEMS transducer, in particular a MEMS loudspeaker or MEMS microphone, can be provided, which simultaneously combines high performance with excellent sound pattern or audio quality. Advantageously, the aforementioned dimensions can be achieved particularly easily by configuring the shaping component accordingly. Preferably, the structure of the shaping component determines the structure of the vibratable membrane comprising vertical and horizontal sections.

The directional indications vertical and horizontal (or lateral) preferably refer to a preferred direction in which the vibratable membrane is oriented for generating or receiving pressure waves of the fluid. Preferably, the vibratable membrane is suspended horizontally between at least two side regions of a carrier, while the vertical direction (direction of interaction with the fluid) for generating or receiving pressure waves is orthogonal to this. In the case of a MEMS loudspeaker, the vertical (interaction) direction corresponds to the vertical sound emission direction of the MEMS loudspeaker. In this case, vertical preferably means the direction of sound emission, while horizontal means a direction orthogonal to it. In the case of a MEMS microphone, the vertical (interaction) direction corresponds to the vertical sound detection direction of the MEMS microphone. In this case, vertical preferably means the direction of sound detection or receiving, while horizontal means a direction orthogonal to it.

The vibratable membrane of the MEMS transducer is of particular importance, as a measurement signal can only be generated or received through horizontal displacement of the vertical sections by pressure waves. Accordingly, the choice of material for the provision of the vibratable membrane is relevant for the performance of the MEMS transducer. According to the invention, it was recognized that an actuator material comprising polymers, which effects an increase in the dipole moment of the polymers through alignment and/or stretching, provides particularly good results.

In a further preferred embodiment, the actuator material is selected from a group comprising a piezoelectric material, a piezoelectric polymer material and/or electroactive polymers (EAP), wherein preferably the actuator material is a piezoelectric polymer material, wherein particularly preferably the piezoelectric polymer material is selected from a group comprising polyvinylidene fluoride (PVDF), polyvinylidene fluoride-co-trifluoroethylene (PVDF-TrFE) and/or poly-L-lactic acid (PLLA).

An actuator material preferably refers to a material that undergoes a change in shape when an electrical voltage is applied, for example stretching, compression or shearing, or conversely generates an electrical voltage when its shape is changed.

Preferred are materials with electric dipoles, which undergo a change in shape when an electric voltage is applied, wherein the orientation of the dipoles and/or of the electric field can determine the preferred direction of the changes in shape.

Preferably, the actuator material can be a piezoelectric material, a piezoelectric polymer material (also piezoelectrical material) and/or electroactive polymers (EAP).

Piezoelectric polymer materials preferably include polymers which exhibit internal dipoles and piezoelectric properties imparted by them. This means that when an external electrical voltage is applied, the piezoelectric polymer materials (analogous to the aforementioned classic piezoelectric materials) undergo a change in shape (e.g. compression, stretching or shearing). An example of a preferred piezoelectric polymer material is polyvinylidene fluoride (PVDF).

Electroactive polymers (EAP) are polymers that change their shape when an electrical voltage is applied. A distinction is usually made between ionic EAPs and electronic EAPs. The mechanism of action of ionic EAPs is based on mass transport (diffusion) of ions. Subgroups of such EAPs are conductive polymers, ionic metal-polymer composites and ionic gels. The mode of action of electronic EAPs, on the other hand, is based on electronic charge transport. This group includes electrostrictive and ferroelectric polymers as well as dielectric elastomers.

Preferably, a piezoelectric polymer material is used as actuator material, wherein particularly preferably the piezoelectric polymer material is selected from a group comprising polyvinylidene fluoride (PVDF), polyvinylidene fluoride-co-trifluoroethylene) (PVDF-TrFE) and/or poly-L-lactic acid (PLLA). The aforementioned materials have advantageously proven to be easily processed and to generate desired piezoelectric properties by alignment and/or stretching.

Piezoelectric polymer materials are advantageously particularly easy to form, i.e. particularly easy to process, exhibit an advantageously low dielectric constant and are particularly suitable for the provision and functional suitability of the vibratable membrane.

In particular, those piezoelectric polymer materials that exhibit a dipole moment substantially perpendicular to the main chain are suitable. This phenomenon is particularly evident in fluorinated polymers, such as PVDF, in which two fluorine atoms are bonded to every second carbon atom along the vinyl chain. The fluorine atoms can be aligned and/or stretched to create a dipole, which increases the dipole moment and thus also the piezoelectric properties. Fluorine exhibits a high electronegativity, while hydrogen exhibits a significantly lower electronegativity. By aligning the fluorine and hydrogen atoms according to the β-phase, taking into account the electronegativities of the atomic species, a particularly strong dipole moment is advantageously generated, thereby enhancing the piezoelectric properties.

The transformation of the actuator material into a so-called β-phase can be of particular importance for increasing the dipole moment. The β-phase is preferably characterized by an all-trans planar zigzag conformation of the atoms, which causes a significant dipole moment (also known as TTTT configuration or conformation). In the case of PVDF, the β-phase is characterized in that most of the fluorine atoms are separated from the hydrogen atoms and a dipole moment is created perpendicular to the main chain. Due to the fact that hydrogen and fluorine exhibit different electronegativities, a strong dipole is created, which accordingly exhibits enhanced piezoelectric properties. In PVDF in particular, the CH₂—CF₂ dipoles are aligned strictly perpendicular to the chain axis (carbon chain). The all-trans molecules are substantially packed in parallel and thus form a crystalline structure, the β-phase. Since dipoles in the β-phase are substantially completely aligned in one direction, there is a particularly pronounced polarization, which results from the summation of the CH₂—CF₂ dipole moments over a unit of volume.

Alignment and/or stretching of the polymers can preferably lead to a conversion of the actuator material, preferably PVDF, into a β-phase. Preferably, the β-phase can be reliably stabilized and/or made more pronounced in order to optimize the piezoelectric properties. When PVDF is used as the piezoelectric polymer material, it is in the β-phase after the preferred steps for producing a MEMS transducer as an actuator layer. The inventors have recognized that the β-phase of actuator materials is particularly well suited to be used for improved performance of MEMS transducers.

In a preferred embodiment, the actuator layer exhibits a relative permittivity εᵣ of 1-15, preferably 5-15, particularly preferably 7-12.

In a preferred embodiment, the actuator layer exhibits piezoelectric charge coefficients of 1-50 pC/N (picocoulomb per Newton), preferably between 1-5 pC/N, particularly preferably from 5-30 pC/N, most preferably from 30-50 pC/N.

The parameter ranges mentioned with regard to the relative permittivity and/or the piezoelectric charge coefficients preferably relate to the actuator layer, i.e. the layer formed by the actuator material after stretching and/or alignment of the polymers. The aforementioned parameter ranges lead in particular to a high performance of the actuator layer and thus improved functionality of the MEMS transducer.

By stretching and/or aligning the polymers of the actuator material, as a result of their contact with the shaping component, the aforementioned parameter ranges can advantageously be achieved reliably and repeatably. Preferably, the stretching and/or alignment of the polymers entails an enhancement of the piezoelectric properties, such as in relation to the piezoelectric charge coefficient, the piezoelectric voltage coefficient and the piezoelectric coupling coefficient.

The piezoelectric charge coefficient preferably describes the relationship between the electrical charge generated per unit of area and an applied mechanical force and is expressed in units of Coulomb/Newton (C/N). This parameter is often used to evaluate the quality of a piezoelectric material.

The piezoelectric voltage coefficient is also referred to as the voltage output constant. It is preferably defined as the ratio between the generated electric field and the applied mechanical stress and is expressed in units of voltage-meter/newton.

The piezoelectric coupling coefficient (less frequently referred to as the electromechanical coupling coefficient) is preferably defined as the ratio between the mechanical energy accumulated in response to an electrical input and the inverse ratio. It also corresponds to the proportion of electrical energy that can be converted into mechanical energy and vice versa.

Furthermore, it is preferred that the actuator material exhibits a modulus of elasticity between approx. 1-5 GPa (gigapascal), preferably between approx. 2-4 GPa, most preferably between approx. 2-3 GPa. The aforementioned ranges of the modulus of elasticity have proven to be advantageous in terms of facilitating shaping on the shaping component such that the meander structure can be achieved with high precision.

In a further preferred embodiment, the method is characterized in that the actuator material is provided in the form of the polymer foil, wherein mechanical stretching of the polymer foil to form an actuator layer into the meander structure comprising the vertical sections and the horizontal sections is performed by means of the shaping component.

Advantageously, the polymer foil can be easily processed, in particular by mechanical stretching, to shape it into the meander structure comprising the vertical and horizontal sections. The polymer foil is characterized by a foil comprising the polymers, which are aligned and/or stretched after mechanical stretching of the polymer foil. The polymer foil is preferably provided in a planar formation. A planar formation preferably means a structure whose extension in a plane (length or width) is many times greater than orthogonal to the plane (thickness). For example, the length or width can be greater than the thickness of a polymer foil by a factor of approx. 2, 3, 10, 20, 50, 100 or more.

In a preferred embodiment, the thickness of the polymer foil is between 100 nm and 50 μm, preferably between 500 nm and 10 μm. Intermediate ranges from the aforementioned ranges can also be preferred, such as 100 nm to 500 nm, 500 nm to 1 μm, 1 μm to 1.5 μm, 1.5 μm to 2 μm, 2 μm to 3 μm, 3 μm to 4 μm, 4 μm to 5 μm, 5 μm to 6 μm, 6 μm to 7 μm, 7 μm to 8 μm, 8 μm to 9 μm, 9 μm to 10 μm, 10 μm to 20 μm, 20 μm to 30 μm, 30 μm to 40 μm or even 40 μm to 50 μm A person skilled in the art will recognize that the aforementioned range limits can also be combined to obtain further preferred ranges, such as 500 nm to 5 μm, 1 μm to 20 μm or even 1500 nm to 10 μm.

Advantageously, the polymer foil can be mechanically stretched particularly easily, i.e. in particular by a small mechanical resistance, in order to produce the meander structure for the vibratable membrane. Advantageously, the polymer foil adapts to the shape of the shaping component with maximum accuracy, such that a desired meander structure can be obtained precisely. At the same time, the polymer foil is advantageously resistant to cracking, such that the reliability of implementation is ensured during the preferred process. Thus, the polymer foil preferably exhibits a high tensile strength, wherein this may depend on the specific material selection for the actuator material. Depending on the material, the tensile strength can preferably be between 20 N/mm² and 300 N/mm², preferably between 50 N/mm²-250 N/mm², particularly preferably between 100 N/mm²-200 N/mm², most preferably between 120 N/mm²-180 N/mm².

The temperature used during mechanical stretching can also be relevant for the resulting vibratable membrane. In preferred embodiments, for example, a temperature above or below the glass transition temperature of the material used can be selected. In the context of the invention, the temperature during the stretching and/or alignment of the actuator material can therefore also be understood as a factor for the alignment of the polymers (or stretching factor).

Mechanical stretching preferably means stretching in such a way that the polymers of the actuator material are aligned and/or stretched by mechanical principles of action in order to increase the dipole moment of the polymers and thus generate enhanced piezoelectric properties. Mechanical stretching is preferably carried out when a polymer foil is provided. Mechanical stretching includes, for example, the application of low pressure to convert the polymer foil into the meander structure. Mechanical stretching also preferably involves the interaction of two shaping components in order to obtain the meander structure of the vibratable membrane.

Stretching the polymer foil preferably achieves an increase in area and/or length along one dimension. An increase in the area and/or length can preferably be 10%, 20%, 30%, 40%, 50%, 60%, 70%, 80%, 90%, 100%, 200%, 300%, 400% or more in relation to an initial area and/or initial length, an increase of 100%, 200%, 300%, 400% meaning an increase by a factor of 2, 3, 4. In particular, this causes the polymers of the actuator material to be stretched along the vertical direction by the mechanical stretching in order to increase the piezoelectric properties.

The advantage of mechanical stretching is that the actuator layer comprising the actuator material obtains a particularly precise C-axis orientation, which is perpendicular to the surface of the vertical sections of the resulting meander structure. A C-axis orientation allows, for example, a transverse piezo effect (piezoelectric effect) to be used for the vibration of the vertical sections of the resulting vibratable membrane. Other orientations may also be preferred and may, for example, involve the utilization of a longitudinal piezoelectric effect to form the horizontal curvatures or vibrations.

In a further preferred embodiment, the method is characterized in that the shaping component exhibits a comb structure comprising comb fingers.

A comb structure is preferably a structure that exhibits a plurality of comb fingers, which are preferably arranged regularly, i.e. in particular that the comb fingers are substantially identical in terms of shape, length, width and thickness. The comb structure preferably also comprises empty regions. An empty region preferably refers to a region of the comb structure where the material of the comb structure is not present. Preferably, a comb structure comprises a regular alternating sequence of a comb finger and an empty region.

The comb structure can be advantageously provided by common methods of semiconductor microsystem technology, for example by etching a substrate. The etched regions of the substrate are referred to as empty regions, while the remaining regions represent the comb fingers. As it is particularly easy to provide the comb structure, the meander structure can be optimized in terms of design, depending on the intended use. For example, the length of the comb fingers preferably corresponds to the length of the vertical sections, wherein the width of the empty regions corresponds to the width of the horizontal sections.

In a further preferred embodiment, the method is characterized in that the shaping component comprises a comb structure comprising comb fingers and the comb structure exhibits openings, wherein the actuator material is applied as a polymer foil to the comb fingers of the comb structure and a low pressure, preferably a vacuum, is applied via the openings, such that partial regions of the polymer foil are mechanically stretched in the direction of the openings, such that a meander structure is formed.

Preferably, the openings are located on a main strand of the comb structure. The main strand of the comb structure preferably refers to the section on which the comb fingers are attached. The openings can be provided by known prior art methods, for example by known etching methods. Preferably, the openings are made in the main strand of the comb structure in such a way that they are positioned between the comb fingers. By applying a low pressure, regions of the polymer foil are mechanically stretched in the direction of the openings, i.e. in particular in the direction of the main strand of the comb structure.

Preferably, the polymer foil is fixed to the comb structure at its end regions, such that fixing the polymer foil after application of the low pressure results in a correspondingly stretched polymer foil. In this case, the entire polymer foil is preferably stretched along one dimension of the comb fingers in a row one behind the other, wherein the degree of stretching or elongation can be adjusted by the level and/or duration of the applied low pressure.

A mechanical resistance of the polymer foil to the application of the low pressure can also preferably be adjusted by the strength with which it is fixed at its end, which leads to a different degree of stretching or elongation of the polymer foil. In the event that it is fixed at its end in a manner that does not allow any relative movement of the polymer foil, the increase in length of the polymer foil due to the shaping of the vertical sections will contribute completely to the stretching of the polymer foil. If it is fixed less strongly at its end, it is possible that the shaping of vertical sections due to application of a low pressure at the opening only partially results from an elongation or stretching of the polymer foil, since a supply of polymer foil from regions outside the comb structure is not completely prevented. Advantageously, the desired height of the vertical sections and the stretching or elongation of the polymer foil can be adjusted independently of each other by adjusting the strength with which the foil is fixed at its end.

In further embodiments, it may also be preferred for the polymer foil to be fixed to the contact surfaces of the comb fingers, such that these regions are not stretched when a low pressure is applied. Those regions of the polymer foil that are stretched in the direction of the openings form the vertical sections after stretching, while those regions that are not stretched form the horizontal sections.

The application of a low pressure preferably means the effect of a pressure that is lower than the pressure that is present between the comb fingers of the comb structure. The low pressure is particularly preferably a vacuum. The low pressure can preferably be lower than the ambient pressure. Preferably, the low pressure is selected from a range comprising approx. 0-100 000 Pa (Pascal), preferably between approx. 0-50 000 Pa, particularly preferably between approx. 0-20 000 Pa, particularly strongly preferably between approx. 0-10 000 Pa, most preferably between approx. 0-5000 Pa. Preferably, the low pressure can be adapted to the mechanical properties, e.g. to the elasticity of a polymer foil.

In the context of the invention, the low pressure can be understood as a stretching factor. Among other things, the stretching of the polymer foil to provide the actuator layer can be regulated by the level of the low pressure. For example, the stretching as such can be regulated by adjusting the low pressure, since the height of the resulting vertical sections (and, in the case of being fixed at its end, longitudinal stretching of the polymer foil) can be adjusted with the value and/or the effective duration of the low pressure. This means that the duration of action, i.e. the time during which the low pressure acts, can also be regarded as a stretching factor. This means that the shape of the vibratable membrane can be adjusted particularly easily using the low pressure.

Preferably, a low pressure is applied through the openings of the comb structure at a temperature between approx. 180° C.-220° C. The temperature used can facilitate the stretching of the polymer foil in the direction of the openings, such that in particular a faster stretching in the direction of the openings is made possible. This is partly due to the fact, without being limited to theory, that at an increased temperature the mechanical tension of the polymer foil is reduced, whereby stretching can be carried out with reduced mechanical resistance. The temperature during the preferred application of the low pressure preferably also represents a stretching factor.

The shape of the comb structure, to whose comb fingers the polymer foil is preferably applied when applying a low pressure, can also be understood as a stretching factor. For example, the height and width of the comb fingers approximately determine the height of the vertical sections and width of the horizontal sections of the resulting vibratable membrane, provided that a low pressure is applied which completely molds the polymer foil to the comb structure.

Preferably, a substantially identical low pressure is applied via each opening in order to achieve the most uniform possible mechanical stretching of the polymer foil. The mechanical stretching through the use of a low pressure can be influenced by the size of the openings and/or the value of the low pressure. The lower the pressure and/or the larger the opening, the faster the mechanical stretching of the polymer foil takes place in order to provide the meander structure. The application of a low pressure leads advantageously to particularly uniform stretching and therefore excellent results in terms of the power and sound performance of the actuator layers formed. Potential damage to the actuator layer is also effectively avoided.

In a further preferred embodiment, the method is characterized in that the actuator material is applied as a polymer foil on a first comb structure, wherein a second comb structure is guided towards the polymer foil and respective comb fingers of the first comb structure and the second comb structure are guided into empty regions, such that the meander structure comprising the vertical sections and the horizontal sections is formed in an interaction of the first comb structure substrate and the second comb structure substrate.

Preferably, the polymer foil is applied to the first comb structure in such a way that the polymer foil lies along the longitudinal axis of the comb fingers. The meander structure is provided by the interaction of the first comb structure and the second comb structure. The interaction preferably means that the first comb structure and the second comb structure are guided together in such a way that the respective longitudinal axes of the comb fingers are inserted into the empty regions of the other comb structure. Consequently, the introduction of the comb fingers of the first comb structure into the empty regions of the second comb structure results in a membrane with a meander structure comprising vertical and horizontal sections.

Preferably, the first comb structure and the second comb structure are guided together in such a way that the comb fingers of the two comb structures are substantially perpendicular to the vertical direction and a horizontal direction of the actuator layer or vibrating membrane provided thereupon. In particular, the comb fingers of the two comb structures are guided together in such a way that the comb fingers are oriented in a sagittal direction.

The length of the vertical sections can preferably be determined by the final distance between the first comb structure and the second comb structure. The final distance between the first comb structure and the second comb structure preferably means the distance that exists after the mechanical stretching has taken place. The greater the final distance, the longer the vertical section. Preferably, the final distance between the first comb structure and the second comb structure refers to the final distance between the tips of the comb fingers. Thus, the final distance in this embodiment is also a stretching factor with which the shape and stretching of the actuator layer can be optimized. The shape and stretching of the actuator layer and thus of the vibratable membrane can also be regulated by the shape of the two comb structures, for example by the length and/or width, for example the length of the vertical sections and/or the shape in a sagittal direction.

Preferably, the final distance between the first comb structure and the second comb structure is determined by a displacement of the first comb structure and the second comb structure.

Preferably, the polymer foil is fixed to the first comb structure at its end regions, such that the meander structure of the vibratable membrane results from fixing the polymer foil after the first comb structure interacts with the second comb structure. The mechanical resistance of the polymer foil can preferably be adjusted by the strength with which it is fixed, such that a higher mechanical resistance can be generated when it is particularly strongly fixed than when it is fixed less strongly. Thus, the fixing of the polymer foil at the end regions of the first comb structure is preferably also a stretching factor.

By combining the choice of the strength with which the polymer foil is fixed at end regions of the first comb structure and the displacement, a particularly precise adjustment can be made for the shape of the meander structure. For example, the length, width, shape and/or rigidity of the vertical and/or horizontal sections can be optimized by selection of the strength with which the polymer foil is fixed, the shape of the comb structure and/or the distance of the displacement.

Preferably, the temperature is below 180° C. while mechanical stretching takes place through interaction between the first and second comb structures. Depending on the temperature level, this can also facilitate stretching in order to reduce the mechanical tension of the polymer foil by means of the temperature effect. The temperature during the interaction of the first comb structure with the second comb structure can also be regarded as a stretching factor.

In preferred embodiments, stretching is achieved by applying a low pressure or by the interaction of the first comb structure and the second comb structure at a temperature that is above or below the glass transition temperature of the polymer foil. By adjusting the temperature, both the process of forming the meander structure and the stretching or alignment of the polymers can be advantageously influenced.

At a temperature above the glass transition temperature, the malleability of the polymer foil is increased, such that a particularly stable meander structure of the membrane can be obtained. At a temperature below the glass transition temperature of the polymers, on the other hand, a particularly pronounced alignment of the polymers can be advantageously achieved.

The temperature used during shaping of the polymer foil is therefore another relevant factor that can be optimized to obtain the meander structure and the piezoelectric properties of the vibratable membrane.

In the context of the invention, stretching factors refer to factors that can be used to regulate the stretching of the polymers of the actuator material. These factors or parameters can differ depending on the embodiment. For example, the stretching factors include low pressure, the shape of the comb structure(s), the fixing of the polymer foil to the comb structure, the displacement of comb structures, temperatures used in the stretching and/or alignment of the polymers, etc.

In a further preferred embodiment, the method is characterized in that the actuator material is provided in the form of the polymer foil, to which at least one layer comprising a mechanical support material and/or a conductive material is additionally applied, wherein the layer comprising the mechanical support material and/or the layer comprising a conductive material also undergoes mechanical stretching upon contact with the shaping component.

Advantageously, mechanical stretching of the polymer foil in combination with stretching of the mechanical support layer eliminates the need for further processing steps, enabling the meander structure to be provided more quickly. For example, mechanical stretching of the mechanical support material combined with stretching of the polymer foil means that it is no longer necessary to coat a mechanical support material.

Thus, it may be preferred to provide the polymer foil together with a mechanical support material, wherein preferably the polymer foil and the mechanical support material are attached to each other, and the polymer foil and the mechanical support material are arranged in combination on the comb fingers of a comb structure. Preferably, there are openings on the main strand of the comb structure, which can be formed by etching processes, for example. By applying a low pressure, preferably a vacuum, the polymer foil in combination with the mechanical support material is accordingly displaced in the direction of the main strand and thus the openings. In particular, those regions that are positioned over the empty regions of the comb structure are displaced in the direction of the main strand. In regions where the polymer foil and the mechanical support material are positioned on the comb fingers, there is correspondingly no stretching in the direction of the main strand or the openings. Consequently, a meander structure can be provided that stretches the polymer foil and the mechanical support material together.

The mechanical stretching of the polymer foil in combination with the mechanical support material can preferably also be achieved by using a first and second comb structure. The polymer foil and the mechanical support material can preferably be provided arranged on top of each other and arranged on the first comb structure in such a way that they are applied along the longitudinal axis of the comb fingers. Preferably, the meander structure is provided by an interaction of the first comb structure and the second comb structure. Preferably, the first comb structure and the second comb structure are guided towards each other in such a way that the comb fingers are brought into the empty regions of the other comb structure accordingly. Consequently, the meander structure can be provided both for the actuator layer and for the mechanical support layer by the interaction of the first comb structure with the second comb structure. It may also be preferred to first provide the meander structure for the polymer foil in order to form an actuator layer and then to coat the mechanical support material.

In preferred embodiments, conductive material is present on and/or below the actuator material. By stretching and/or aligning the actuator material in combination with the conductive material, a top electrode (on the actuator material) and/or bottom electrode (below the actuator material) can advantageously be provided after stretching in addition to the actuator layer.

In further preferred embodiments, a conductive material can be identical to the support material such that, for example, a bottom and/or top electrode is simultaneously a mechanical support layer.

The preferred additional application of at least one further layer comprising a mechanical support material and/or a conductive material on the polymer foil, which together undergoes mechanical stretching upon contact with the shaping component, is particularly preferred if the at least one further layer is stretchable, i.e. mechanically deformable without sustaining damage or cracks. A stretchable electrically conductive material can preferably be a coating comprising, for example, carbon nanotubes. If the at least one further layer comprising a mechanical support material and/or a conductive material does not exhibit sufficient elasticity for mechanical stretching, it is preferred that the at least one further layer is applied by a coating only after the polymer foil has been shaped.

In a further preferred embodiment, the method is characterized in that, after mechanical stretching, the actuator material in the form of the polymer foil is additionally coated with at least one layer comprising a mechanical support material and/or a conductive material. In this way, a support layer and/or a layer comprising an electrically conductive material is obtained, which exhibits the meander structure according to the stretched polymer foil, without the support material or the electrically conductive material itself having to be stretched.

Preferably, the at least one layer comprising the mechanical support material and/or the conductive material is applied by using a coating process within a coating system. The coating process can, for example, be selected from a group comprising spray coating, mist coating and/or vapor coating. The aforementioned coating processes are known to the person skilled in the art and are advantageously easy to carry out.

Preferably, the coating takes place within a coating system, which can be a physical coating system or chemical coating system, preferably a plasma-supported chemical coating system, low-pressure chemical and/or epitaxial coating system.

Preferably, the coating takes place within a temperature range at which there is no change to the already aligned polymers of the actuator material, such that the enhanced piezoelectric properties are particularly reliably retained.

In particular, it is preferred that all steps of the method for providing a MEMS transducer which are carried out after stretching/alignment of the polymers of the actuator material are carried out at a temperature at which the enhanced piezoelectric properties of the actuator layer are not compromised. It is particularly preferred for process steps for providing a MEMS transducer after stretching/alignment of the polymers of the actuator material that temperatures of more than 300° C., preferably more than 200° C. or more than 150° C. are avoided.

In a further preferred embodiment, the method is characterized in that the vibratable membrane comprises a layer comprising a conductive material which acts as a top and/or bottom electrode.

The top and/or bottom electrode preferably means a layer comprising an electrically conductive material which extends over the entire surface of the vibratable membrane. Preferably, the layer is placed in contact with an electrode pad as an electrode, wherein preferably the conductive material in combination with the electrode can also be referred to as a top and/or bottom electrode, wherein preferably the electrode is present with electronics for providing an electrical voltage and/or an electrical current. Preferably, the electrode is attached at the end such that it is possible to actuate the actuator layer from the electrode or an electrical signal can be read out at the electrode due to a corresponding change in the shape of the actuator layer.

The layer of a conductive material, preferably a metal, in the sense of a top or bottom electrode is particularly preferably present as a continuous or full-surface or contiguous layer of the vibratable membrane, which forms a substantially homogeneous area. The designations top and bottom preferably refer to the position of the conductive material, such that in a cross-section it can be said that the top electrode comprises a conductive material above the actuator layer and the bottom electrode comprises a conductive material below the actuator layer.

By means of the layer made of a conductive material, preferably metal, the two or more vertical sections can advantageously be placed in contact with an end-side electrode or an electrode pad.

End-side preferably means a positioning of the at least one electrode such that contact can be made to a current or voltage source at one end of the vibratable membrane, preferably at an end at which the membrane is suspended from the carrier.

In preferred embodiments, the producible MEMS transducer comprises two end-side electrodes. Preferably, contact with electronics, e.g. a current or voltage source, can be made with the electrodes at opposite ends of the vibratable membrane between which the two or more vertical sections are present, such that the actuator layer(s) in the vertical sections can be controlled by means of the end-side electrodes.

The end-side provision of the electrodes is thus preferably distinguished from a form of contact which drives the respective vertical sections with separate electrodes or, in the case of a MEMS microphone, taps generated electrical signals. Preferably, the MEMS transducer thus comprises exactly one or exactly two electrodes for end-side contact and no further electrodes (pads) for contact with the center of vertical sections.

Preferably, the layer of an actuator material in the vertical sections serves as a component of a mechanical biomorph, wherein a lateral curvature of the vertical sections is caused by driving the actuator layer via the electrode or wherein a corresponding electrical signal is generated by an induced lateral curvature.

In a further preferred embodiment, the method is characterized in that the vibratable membrane comprises a layer comprising a conductive material, wherein the conductive material is selected from a group comprising platinum, tungsten, (doped) tin oxide, monocrystalline silicon, polysilicon, molybdenum, titanium, tantalum, titanium-tungsten alloy, metal silicide, aluminum, graphite, copper, wherein preferably the conductive material is a superelastic metal, wherein particularly preferably the conductive material exhibits a fiber reinforcement, wherein for the fiber reinforcement the conductive material exhibits fibers, wherein most preferably the fibers comprise carbon.

The conductive materials selected from a group of a group comprising platinum, tungsten, (doped) tin oxide, monocrystalline silicon, polysilicon, molybdenum, titanium, tantalum, titanium-tungsten alloy, metal silicide, aluminum, graphite, copper are particularly suitable for being applied to the actuator layer as part of a coating process, in particular after the polymer foil has been mechanically stretched.

Conductive materials such as superelastic metal or conductive material which exhibit fiber reinforcement are particularly suitable for mechanical stretching in combination with the polymer foil.

Superelastic metals preferably refer to metals that belong to the superelastic materials and exhibit so-called pseudoelastic or superelastic behavior. Under high stress, they can deform reversibly to a high degree of elongation. This “elastic” deformation can exceed the elasticity of metals by a factor of up to twenty. The cause of this behavior is a phase transformation within the material. Various metal alloys can be used here, e.g. alloys comprising copper, zinc and aluminum or copper, aluminum and nickel or nickel and titanium.

Fiber-reinforced materials, such as materials reinforced with fibers comprising carbon, can have an advantageous effect on both the support function and the electrical conductivity. Thus, a higher mechanical resistance can be advantageously generated by the fiber reinforcement, such that the stress gradient that is generated is increased during the deformation of a vertical section and at the same time the electrical conductivity can be increased by selecting the corresponding crystal structure of the fibers, e.g. the carbon.

In a further preferred embodiment, the method is characterized in that the vibratable membrane comprises a layer comprising a mechanical support material, wherein the mechanical support material is selected from a group comprising monocrystalline silicon, polycrystalline silicon and/or doped polycrystalline silicon.

The aforementioned materials have proven to be particularly advantageous for acting as a support layer. Furthermore, they are particularly well suited to being applied to the actuator layer as part of a coating process, e.g. after mechanical stretching.

In a further preferred embodiment, the method is characterized in that the actuator material is provided as a polymer liquid and the shaping component is immersed in the polymer liquid, wherein, after the shaping component comes into contact with the polymer liquid, the polymers of the actuator material undergo an alignment such that a dipole moment of the polymers is increased and piezoelectric properties of the actuator material are enhanced, wherein preferably the shaping component comprises a comb structure comprising comb fingers.

The polymers of the polymer liquid are aligned by immersing the shaping component in the polymer liquid. In preferred embodiments, the shaping component can be provided with an intermediate coating for this purpose, which causes the polymers to be aligned. It may also be preferred that the shaping component is formed from a semiconductor material, wherein a crystal orientation is used to align the growing polymer layer. By selecting or configuring the shaping component accordingly, a desired alignment of the polymers of the polymer liquid can be advantageously achieved and piezoelectric properties of the resulting actuator layer can be increased.

Preferably, the shaping component is immersed in the polymer liquid at a temperature that is above the glass transition temperature of the polymer liquid, such that the alignment of the polymers can be provided more easily.

In a further preferred embodiment, the method is characterized in that, after the shaping component is brought into contact with the polymer liquid, the polymer liquid adheres to the shaping component and hardens to form the actuator layer comprising vertical and horizontal sections, wherein preferably after forming the actuator layer, the actuator layer is coated with a layer comprising a conductive material and/or a mechanical support material.

Alignment of the polymers of the polymer liquid can take place in particular (in the viscous state) if the alignment is frozen or obtained after immersion of the shaping component.

In a further preferred embodiment, the method is characterized in that at least a partial section of the shaping component, preferably an entire section, is removed after contact with the actuator material, preferably by an etching process and/or by a thermal treatment.

The etching process and/or thermal treatment can advantageously expose the meander structure comprising vertical and horizontal sections, such that the vibrational capability is provided.

An etching process preferably refers to a process for etching, i.e. removing material in order to remove the shaping component. Preferably, the etching process is selected from a group comprising wet chemical etching processes and/or dry etching processes, preferably physical and/or chemical dry etching processes, particularly preferably constituted by reactive ion etching and/or reactive ion deep etching (Bosch process), or by a combination of the aforementioned etching processes.

The aforementioned etching processes are known to the person skilled in the art and can be selected accordingly to ensure efficient removal of the shaping component.

Preferably, the shaping component can also be removed by thermal treatment. A thermal treatment preferably refers to a process for removing the shaping component by means of a heat effect. The choice of temperature depends on the material comprising the shaping component.

After exposure of the meander structure and provision of the vibratable membrane, it is placed in contact with the carrier. Preferably, the vibratable membrane is placed in contact with the support at its end, such that the membrane extends along a horizontal direction.

In a further preferred embodiment, the method is characterized in that the shaping component and/or the carrier comprises a material selected from a group comprising monocrystalline silicon, polysilicon, silicon dioxide, silicon carbide, silicon germanium, silicon nitride, nitride, germanium, carbon, gallium arsenide, gallium nitride, indium phosphide and/or glass.

These materials are easy and inexpensive to process in semiconductor and/or microsystem production and are suitable for large-scale applications. In particular, the carrier and/or the housing can be produced flexibly due to the materials and/or production methods. In particular, it is preferably possible to produce the MEMS transducer comprising a vibratable membrane together with a carrier in a (semiconductor) process, preferably on a wafer. This further simplifies and reduces the cost of production, such that a compact and robust MEMS transducer can be produced cost-effectively.

In a preferred embodiment of the invention, the carrier comprises two side regions, preferably four side regions, between which the vibratable membrane is arranged in a horizontal direction.

The carrier is preferably a frame structure, which is substantially formed by a continuous outer border in the form of side walls of a free planar region. The frame structure is preferably stable and rigid. In the case of an angular frame shape (triangular, square, hexagonal or generally polygonal outline), the individual side regions, which preferably substantially form the frame structure, are referred to in particular as side walls. The vibratable membrane is preferably held by at least two side walls of the carrier.

Preferably, the carrier comprises four side regions, preferably with additional end faces, which are generally parallel to the drawn cross-section. These further two side walls span the frame structure.

Preferably, the carrier can be provided by the shaping component, for example in embodiments in which mechanical stretching is preferred. For example, it may be preferred that in the case of mechanical stretching, the housing of the MEMS transducer is provided by the interaction of two shaping components.

In a further aspect, the invention relates to a MEMS transducer for interacting with a volume flow of a fluid producible according to a method as described above.

The average person skilled in the art will recognize that technical features, definitions and advantages of preferred embodiments of the described method for producing a MEMS transducer also apply to the MEMS transducer and vice versa.

It was surprising that preferred method steps for producing the MEMS transducer resulted in a MEMS transducer characterized by excellent acoustic, electrical and mechanical properties, in particular with regard to the vibratable membrane. The shape of the meander structure could be adjusted with particular precision, for example by the selection of stretching factors. In particular, the shape of the vertical and/or horizontal sections can be determined with particular ease. The displacement of the vertical sections can be advantageously regulated by the stretching and/or alignment of the polymers of the actuator material, such that the MEMS transducer produced can be used efficiently in a plurality of applications. Consequently, preferred embodiments of the method have an effect on structural and thus also on functional properties of the MEMS transducer.

The improved properties of the MEMS transducer are particularly evident during operation. Due to the enhancement of the piezoelectric properties, a vibratable membrane is advantageously provided which generates a correspondingly higher electrical measurement signal when the vertical sections are displaced. Conversely, by applying an electrical voltage, a greater displacement of the vertical sections can be generated, such that a higher volume flow of a fluid (in particular air) can be expelled. The MEMS transducer is therefore characterized by a particularly high level of performance with the desired acoustic properties.

Advantageously, the MEMS transducer exhibits an actuator layer with excellent piezoelectric properties, such that the vibratable membrane in particular exhibits improved performance. In this way, greater displacements of the vertical sections can be advantageously achieved if sound pressure waves are to be detected in the case of a MEMS microphone or sound pressure waves are to be emitted in the case of a MEMS loudspeaker.

The invention will be explained below with reference to figures and examples. The examples and figures serve to illustrate preferred embodiments of the invention without limiting it.

### FIGURES

### Brief Description of the Figures

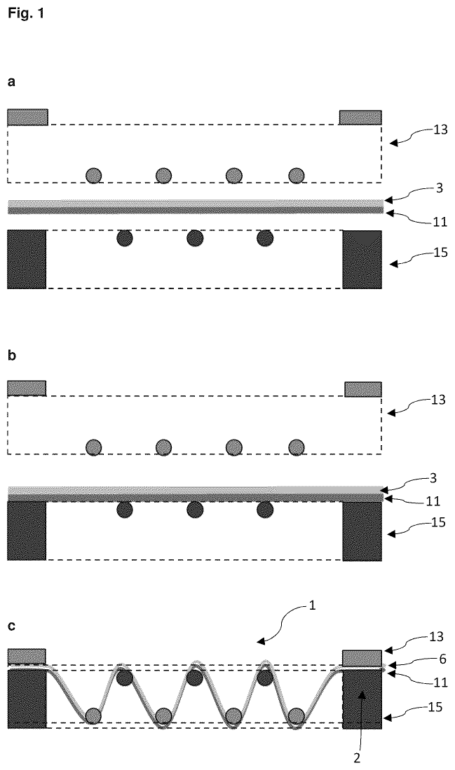

FIG. 1 Schematic representation of preferred method steps for producing a MEMS transducer

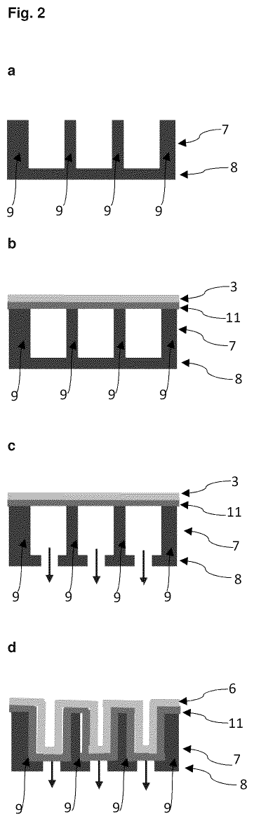

FIG. 2 Further schematic representation of preferred method steps for producing a MEMS transducer

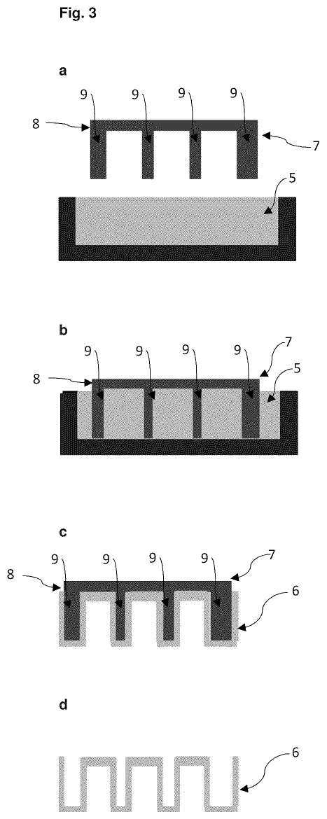

FIG. 3 Further schematic representation of preferred method steps for producing a MEMS transducer

### DETAILED DESCRIPTION OF THE FIGURES

FIG. 1 shows a schematic representation of preferred method steps.

FIG. 1a shows a first shaping component 13 and a second shaping component 15. The first shaping component or first comb structure 13 and the second shaping component or second comb structure 15 are configured as comb structures, i.e. they comprise comb fingers 9 which, however, point out of or into the sheet plane in the illustration.

Furthermore, the actuator material is shown in the form of a polymer foil 3 and a layer comprising a mechanical support material 11. The polymer foil 3 is applied to the mechanical support material 11.

FIG. 1b shows that the polymer foil 3 and the layer comprising a mechanical support material 11 are applied to the comb fingers of the second comb structure 15.

FIG. 1c shows that the first comb structure 13 is guided in the direction of the polymer foil 3 and the layer comprising the mechanical support material 11. Thereby, respective comb fingers of the first comb structure 13 are guided into empty regions of the second comb structure 15. Consequently, the meander structure for an actuator layer 6 is formed in an interaction of the first comb structure 13 and the second comb structure 15, wherein the meander structure exhibits vertical sections and horizontal sections.

The final distance between the first comb structure 13 and the second comb structure 15, in particular between the tips of the comb fingers, can advantageously determine the length of the vertical sections of the vibratable membrane. The shape of the two comb structures 13, 15 also regulates the shape of the actuator layer and thus of the vibratable membrane. The final distance between the first comb structure 13 and the second comb structure 15 is determined by a displacement of the comb structures 13, 15.

The polymer foil 3 is preferably fixed at the end regions of the comb structure 13 and/or 15, such that the polymer foil 3 is stretched or elongated by the interaction of the first comb structure 13 with the second comb structure 15 in order to obtain a corresponding meander structure.

FIG. 2 shows further preferred method steps for configuring the meander structure.

FIG. 2a shows a shaping component 7 in the form of a comb structure 7, which exhibits comb fingers 9. Advantageously, the structure of the comb fingers 9 makes it particularly easy to obtain the meander structure for the structure of the vibratable membrane.

In FIG. 2b, the actuator material in the form of a polymer foil 3 and the layer comprising the mechanical support material 11 are provided, wherein these are applied to the comb fingers 9 of the comb structure 7.

FIG. 2c shows that the comb structure exhibits openings, wherein they are formed on a main strand 8 of the comb structure 7, on which the comb fingers 9 are arranged. The arrows show the application of a low pressure, such that partial regions of the polymer foil 3 and the layer comprising the mechanical support material 11 are stretched.

During the application of the low pressure, the polymer foil 3 is fixed at the end regions of the chamber structure 7, such that the polymer foil 3 is stretched accordingly. Preferably, the entire polymer foil is stretched along one dimension of the comb fingers 9 arranged in a row one behind the other, wherein the degree of stretching or elongation can be adjusted by the level and/or duration of the applied low pressure.

In particular, a substantially identical low pressure is applied via each opening in order to achieve the most uniform possible mechanical stretching of the polymer foil 3. The mechanical stretching through the use of a low pressure can be influenced by the size of the openings and/or the magnitude of the low pressure. The lower the pressure and/or the larger the opening, the faster the mechanical stretching of the polymer foil 3 takes place in order to provide the meander structure.

FIG. 3 shows a further schematic representation of preferred method steps.

In FIG. 3a, a polymer liquid 3 and the shaping component 7 are provided, wherein the shaping component 7 is present as a comb structure 7 comprising comb fingers 9.

FIG. 3b shows that the comb structure 7 is immersed in the polymer liquid 5. After the comb structure 7 is placed in contact with or immersed in the polymer liquid 5, the polymers of the actuator material or the polymer liquid 5 are aligned in such a way that a dipole moment of the polymers is increased and piezoelectric properties of the actuator material are enhanced. The polymers of the polymer liquid 5 are aligned by immersing the shaping component 7 in the polymer liquid 5.

FIG. 3c shows that the polymer liquid 5 adheres to the comb structure 7 and hardens to form the actuator layer 6 as a meander structure comprising vertical and horizontal sections.

Once the actuator layer 6 has been formed, the comb structure 7 is removed, which can be achieved by an etching process and/or thermal treatment, for example (see FIG. 3d).

### LITERATURE

Iman Shahosseini, Elie LEFEUVRE, Johan Moulin, Marion Woytasik, Emile Martincic, et al. Electromagnetic MEMS Microspeaker for Portable Electronic Devices. Microsystem Technologies, Springer Verlag (Germany), 2013, pp.10. <hal-01103612>
F. Stoppel, C. Eisermann, S. Gu-Stoppel, D. Kaden, T. Giese and B. Wagner, NOVEL MEMBRANE-LESS TWO-WAY MEMS LOUDSPEAKER BASED ON PIEZOELECTRIC DUAL-CONCENTRIC ACTUATORS, Transducers 2017, Kaohsiung, TAIWAN, Jun. 18-22, 2017.
Bert Kaiser, Sergiu Langa, Lutz Ehrig, Michael Stolz, Hermann Schenk, Holger Conrad, Harald Schenk, Klaus Schimmanz and David Schuffenhauer, Concept and proof for an all-silicon MEMS microspeaker utilizing air chambers Microsystems & Nanoengineering volume 5, Article number: 43 (2019).
Da Silva, Aline Bruna, et al. Effect of drawing on the dielectric properties and polarization of pressed solution cast β-PVDF films. Journal of materials science 45.15 (2010): 4206-4215.
Gade, Harshal, Sreevalli Bokka, and George G. Chase. Polarization treatments of electrospun PVDF fiber mats. Polymer 212 (2021): 123152.

### REFERENCE LIST

1 Vibratable membrane
3 Polymer foil
5 Polymer liquid
6 Actuator layer
7 Shaping component, preferably as a comb structure
8 Main strand
9 Comb fingers
11 Layer comprising a mechanical support material, support layer
13 First shaping component, preferably as a first comb structure
15 Second shaping component, preferably as a second comb structure

1. A method for producing a MEMS transducer for interacting with a volume flow of a fluid comprising
a carrier
a vibratable membrane for generating or receiving pressure waves of the fluid in a vertical direction, wherein the vibratable membrane is held by the carrier,
the vibratable membrane exhibits a meander structure with vertical sections and horizontal sections, wherein the vertical sections are configured substantially parallel to the vertical direction and the horizontal sections connect the vertical sections to one another, and wherein the vibratable membrane comprises at least one actuator layer made of an actuator material and is in contact with at least one electrode, such that the vertical sections can be induced into horizontal vibrations by driving the at least one electrode or such that an electrical signal can be generated at the at least one electrode when the vertical sections are induced to vibrate horizontally wherein the method comprises the following steps:
a) providing at least one shaping component for configuring the vibratable membrane with the actuator layer in the form of a meander structure,
b) providing an actuator material comprising polymers, wherein the actuator material is present in the form of a polymer foil or a polymer liquid, and
c) placing the shaping component in contact with the actuator material for shaping the actuator layer, wherein during the contact between the shaping component and the actuator material, the polymers of the actuator material are aligned and/or stretched such that a dipole moment of the polymers is increased and piezoelectric properties of the actuator material are enhanced.

2. The method according to the preceding claim wherein the actuator material is selected from the group consisting of a piezoelectric material, a piezoelectric polymer material and electroactive polymers (EAP).

3. The method according to claim 1 wherein the actuator layer exhibits a relative permittivity εᵣ of 1-15 and/or the actuator layer exhibits piezoelectric charge coefficients of 1-50 pC/N.

4. The method according to claim 1 wherein the actuator material is provided in the form of the polymer foil, wherein mechanical stretching of the polymer foil to form an actuator layer into the meander structure comprising the vertical sections and the horizontal sections is performed by means of the shaping component.

5. The method according to claim 1, wherein the shaping component exhibits a comb structure comprising comb fingers.

6. The method according to claim 1, wherein the shaping component comprises a comb structure comprising comb fingers and the comb structure exhibits openings, wherein the actuator material is applied as a polymer foil to the comb fingers of the comb structure, and a low pressure is applied via the openings such that partial regions of the polymer foil are mechanically stretched in the direction of the openings such that a meander structure is formed.

7. The method according to claim 1, wherein the actuator material is applied as a polymer foil to a first comb structure, wherein a second comb structure is guided in the direction of the polymer foil and respective comb fingers of the first comb structure and the second comb structure are guided into empty regions, such that the meander structure comprising the vertical sections and the horizontal sections is formed in an interaction of the first comb structure and the second comb structure.

8. The method according to claim 1, wherein the actuator material is provided in the form of the polymer foil, to which at least one layer comprising a mechanical support material and/or a conductive material is additionally applied, wherein the layer comprising the mechanical support material and/or the layer comprising a conductive material also undergoes mechanical stretching upon contact with the shaping component.

9. The method according to claim 1, wherein after mechanical stretching, the actuator material in the form of the polymer foil is additionally coated with at least one layer comprising a mechanical support material and/or a conductive material.

10. The method according to claim 1, wherein the vibratable membrane comprises a layer comprising a conductive material, wherein the conductive material is selected from the group consisting of platinum, tungsten, (doped) tin oxide, monocrystalline silicon, polysilicon, molybdenum, titanium, tantalum, titanium-tungsten alloy, metal silicide, aluminum, graphite, and copper.

11. The method according to claim 1, wherein the vibrating membrane comprises a layer comprising a mechanical support material, wherein the mechanical support material is selected from the group consisting of monocrystalline silicon, polycrystalline silicon and doped polycrystalline silicon.

12. The method according to claim 1, wherein the actuator material is provided as a polymer liquid and the shaping component is immersed in the polymer liquid, wherein after placing the shaping component in contact with the polymer liquid, the polymers of the actuator material undergo an alignment such that a dipole moment of the polymers is increased and piezoelectric properties of the actuator material are enhanced.

13. The method according to claim 1, wherein after placing the shaping component in contact with the polymer liquid, the polymer liquid adheres to the shaping component and hardens to form the actuator layer comprising vertical and horizontal sections.

14. The method according to claim 1, wherein at least a partial section of the shaping component is removed after contact with the actuator material.

15. A MEMS transducer for interacting with a volume flow of a fluid producible according to a method according to claim 1.

16. The method of claim 2, wherein the actuator material is a piezoelectric polymer material.

17. The method according to claim 16, wherein the piezoelectric polymer material is selected from a group consisting of polyvinylidene fluoride (PVDF), polyvinylidene fluoride-co-trifluoroethylene (PVDF-TrFE) and poly-L-lactic acid (PLLA).

18. The method according to claim 16, wherein the conductive material is a superelastic metal or wherein the conductive material comprises a fiber reinforcement, wherein for the fiber reinforcement the conductive material comprises fibers.

19. The method according to claim 12 wherein the shaping component comprises a comb structure comprising comb fingers.

20. The method according to claim 13 wherein after the actuator layer has been formed, the actuator layer is coated with a layer comprising a conductive material and/or a mechanical support material.
